(19) United States
(12) Patent Application Publication
(10) Pub. No.: US 2023/0405725 A1
(43) Pub. Date: Dec. 21, 2023

(54) LASER PROCESSING METHOD, SEMICONDUCTOR DEVICE MANUFACTURING METHOD, AND LASER PROCESSING DEVICE

(71) Applicants: HAMAMATSU PHOTONICS K.K., Hamamatsu-shi (JP); National University Corporation Tokai National Higher Education and Research System, Nagoya-shi, (JP)

(72) Inventors: Daisuke KAWAGUCHI, Hamamatsu-shi (JP); Atsushi TANAKA, Nagoya-shi (JP); Toshiki YUI, Hamamatsu-shi (JP); Tomomi ARATANI, Hamamatsu-shi (JP)

(73) Assignees: HAMAMATSU PHOTONICS K.K., Hamamatsu-shi (JP); National University Corporation Tokai National Higher Education and Research System, Nagoya-shi (JP)

(21) Appl. No.: 18/208,432

(22) Filed: Jun. 12, 2023

(30) Foreign Application Priority Data
Jun. 15, 2022 (JP) 2022-096476

(51) Int. Cl. B23K 26/364; H01L 21/78; H01L 21/268

(52) U.S. Cl. CPC B23K 26/364; H01L 21/78; H01L 21/268

(57) ABSTRACT

A laser processing method includes: a forming step of forming a plurality of modified spots along an imaginary plane inside a work piece by irradiating an inside of the work piece with laser light from a surface. The work piece includes a first region and second region when viewed in a direction perpendicular to the surface. In the forming step, a plurality of modified spot rows formed of the plurality of modified spots arranged along a boundary between the first region and the second region are formed in the second region, the plurality of modified spot rows being arranged along a direction intersecting an arrangement direction of the plurality of modified spots, and a crack extending from the second region to the first region is formed by forming the plurality of modified spot rows.

### TECHNICAL FIELD

One aspect of the present disclosure relates to a laser processing method, a semiconductor device manufacturing method, and a laser processing device.

### BACKGROUND

A processing method has been known in which modified regions are formed inside a work piece such as a semiconductor wafer by irradiating the work piece with laser light and a semiconductor member such as a semiconductor substrate is cut off from the work piece by separating the semiconductor member with the modified regions as the boundary (for example, refer to Japanese Unexamined Patent Publication No. 2017-183600 and Japanese Unexamined Patent Publication No. 2017-057103).

### SUMMARY

### Technical Problem

In the processing method described above, it is preferable that the processing time is short, and it is preferable that a cut surface is flat. In addition, it is preferable that the influence of laser irradiation on the work piece is small.

Therefore, one aspect of the present disclosure is intended to provide a laser processing method, a semiconductor device manufacturing method, and a laser processing device capable of shortening the processing time, improving the flatness of a cut surface, and reducing the influence of laser irradiation on a work piece.

### Solution to Problem

[1] According to one aspect of the present disclosure, there is provided “a laser processing method for cutting a work piece along an imaginary plane facing a surface of the work piece inside the work piece, the method including: a forming step of forming a plurality of modified spots along the imaginary plane by irradiating an inside of the work piece with laser light from the surface. The work piece includes a first region and second region when viewed in a direction perpendicular to the surface. In the forming step, a plurality of modified spot rows formed of the plurality of modified spots arranged along a boundary between the first region and the second region are formed in the second region, the plurality of modified spot rows being arranged along a direction intersecting an arrangement direction of the plurality of modified spots, and a crack extending from the second region to the first region is formed by forming the plurality of modified spot rows.”

In the laser processing method, a crack extending from the second region to the first region is formed by forming the plurality of modified spot rows in the second region. Since a crack is formed by extending from the second region to the first region in such a manner, for example, compared to when a crack is formed in the first region by forming the modified spots in the first region, the processing time can be shortened, and the flatness of a cut surface can be improved. In addition, in the laser processing method, a crack extending from the second region to the first region is formed by forming the plurality of modified spot rows in the second region. Accordingly, the influence of laser irradiation on the first region can be reduced. As a result, for example, when a device portion is formed in the first region, the influence of laser irradiation on the device portion can be reduced. Therefore, according to the laser processing method, the processing time can be shortened, the flatness of the cut surface can be improved, and the influence of laser irradiation on the work piece can be reduced. Incidentally, the finding that a crack extending from the second region to the first region can be formed by forming the modified spot rows formed of the plurality of modified spots, which are arranged along the boundary between the first region and the second region, in the second region so as to be arranged along the direction intersecting the arrangement direction of the plurality of modified spots is a finding discovered by the inventors.

[2] In the laser processing method according to one aspect of the present disclosure described in [1], “in the forming step, the plurality of modified spot rows may be formed in the second region such that the crack is formed over an entirety of the first region.” In this case, the processing time can be further shortened, and the flatness of the cut surface can be further improved.

[3] In the laser processing method according to one aspect of the present disclosure described in [1] or [2], “the plurality of modified spot rows may include a first modified spot row, and a second modified spot row disposed closer to the first region than the first modified spot row, and in the forming step, after the first modified spot row is formed, the second modified spot row may be formed.” In this case, a crack easily extends from the second region to the first region, so that the processing time can be further shortened and the flatness of the cut surface can be further improved. Incidentally, the finding that when the plurality of modified spot rows are formed in order of increasing distance from the first region, a crack easily extends from the second region to the first region is a finding discovered by the inventors.

[4] In the laser processing method according to one aspect of the present disclosure described in any one of [1] to [3], “the second region may include a portion surrounding the first region when viewed in the direction perpendicular to the surface.” In this case, a crack can suitably extend from the second region to the first region, so that the processing time can be further shortened and the flatness of the cut surface can be further improved.

[5] In the laser processing method according to one aspect of the present disclosure described in any one of [1] to [4], “in the forming step, at least two modified spot rows included in the plurality of modified spot rows may be simultaneously formed by branching the laser light and by performing an irradiation with the branched laser light.” In this case, a crack easily extends from the second region to the first region, so that the processing time can be further shortened and the flatness of the cut surface can be further improved. Incidentally, the finding that when at least two modified spot rows are simultaneously formed by branching the laser light and by performing an irradiation with the branched laser light, a crack easily extend from the second region to the first region is a finding discovered by the inventors.

[6] In the laser processing method according to one aspect of the present disclosure described in any one of [1] to [5], “the second region may include a grid-shaped portion including a plurality of linear portions, and the first region may include a plurality of rectangular portions surrounded by the plurality of linear portions.” In this case, a crack easily extends from the second region to the first region, so that the processing time can be further shortened and the flatness of the cut surface can be further improved. In addition, for example, a cutting region having a grid shape for dicing a semiconductor wafer can be used as the second region.

[7] In the laser processing method according to one aspect of the present disclosure described in [6], “when one linear portion included in the plurality of linear portions is defined as a reference linear portion, and a region on one side of the reference linear portion with respect to a center line of the reference linear portion extending along an extending direction of the reference linear portion when viewed in the direction perpendicular to the surface is defined as a first portion, and a region on the other side of the reference linear portion with respect to the center line is defined as a second portion, in the forming step, at least one modified spot row included in the plurality of modified spot rows may be formed in the first portion, and at least one modified spot row included in the plurality of modified spot rows may be formed in the second portion.” In this case, a crack easily extends from the second region to the first region, so that the processing time can be further shortened and the flatness of the cut surface can be further improved.

[8] In the laser processing method according to one aspect of the present disclosure described in [7], “the at least one modified spot row formed in the first portion may include a plurality of first modified spot rows, and the at least one modified spot row formed in the second portion may include a plurality of second modified spot rows. In the forming step, the plurality of first modified spot rows may be formed in the first portion in order of proximity to the center line, and the plurality of second modified spot rows may be formed in the second portion in order of proximity to the center line.” In this case, a crack easily extends from the second region to the first region, so that the processing time can be further shortened and the flatness of the cut surface can be further improved.

[9] In the laser processing method according to one aspect of the present disclosure described in any one of [1] to [8], “a material of the work piece may include gallium nitride, silicon carbide, sapphire, silicon, gallium arsenide, magnesium oxide, magnesium fluoride, calcium fluoride, or mica.” Even in this case, the processing time can be shortened, the flatness of the cut surface can be improved, and the influence of laser irradiation on the work piece can be reduced.

[10] In the laser processing method according to one aspect of the present disclosure described in any one of [1] to [9], “the work piece may have a chip shape, a wafer shape, or an ingot shape.” Even in this case, the processing time can be shortened, the flatness of the cut surface can be improved, and the influence of laser irradiation on the work piece can be reduced.

[11] In the laser processing method according to one aspect of the present disclosure described in any one of [1] to [10], “the work piece may be made of a semiconductor material.” In this case, a semiconductor object made of a semiconductor material can be suitably cut as the work piece.

[12] In the laser processing method according to one aspect of the present disclosure described in any one of [1] to [11], “the first region may be a region for forming a device portion, and the second region is a region in which the device portion is not formed.” In this case, the influence of laser irradiation on the device portion can be reduced.

[13] In the laser processing method according to one aspect of the present disclosure described in [12], “in the forming step, in a state where the device portion is formed in the first region, the plurality of modified spot rows may be formed in the second region.” In this case, the influence of laser irradiation on the device portion formed in the first region can be reduced.

[14] In the laser processing method according to one aspect of the present disclosure described in [12], “in the forming step, in a state where the device portion is not formed in the first region, the plurality of modified spot rows may be formed in the second region.” In this case, the influence of laser irradiation on the first region before the device portion is formed can be reduced, and as a result, the influence of laser irradiation on the device portion formed in the first region can be reduced.

[15] “The laser processing method according to one aspect of the present disclosure described in any one of [1] to may further include a step of separating the work piece with the imaginary plane as a boundary after the forming step.” In this case, the work piece can be suitably separated.

[16] According to one aspect of the present disclosure, there is provided “a semiconductor device manufacturing method using the laser processing method according to any one of [1] to [15], the work piece being made of a semiconductor material, the method including: the forming step; and a step of forming a device portion in the first region.” According to the semiconductor device manufacturing method, for the above-described reasons, the processing time can be shortened, the flatness of a cut surface can be improved, and the influence of laser irradiation on the work piece can be reduced.

[17] According to one aspect of the present disclosure, there is provided “a laser processing device that cuts a work piece along an imaginary plane facing a surface of the work piece inside the work piece, the device including: a stage that supports the work piece; and a laser irradiation unit that forms a plurality of modified spots along the imaginary plane by irradiating an inside of the work piece with laser light from the surface. The work piece includes a first region and second region when viewed in a direction perpendicular to the surface. The laser irradiation unit forms a plurality of modified spot rows in the second region, the plurality of modified spot rows being formed of the plurality of modified spots arranged along a boundary between the first region and the second region, the plurality of modified spot rows are arranged along a direction intersecting an arrangement direction of the plurality of modified spots, and a crack extending from the second region to the first region is formed by forming the plurality of modified spot rows.” According to the laser processing device, for the above-described reasons, the processing time can be shortened, the flatness of a cut surface can be improved, and the influence of laser irradiation on the work piece can be reduced.

According to one aspect of the present disclosure, it is possible to provide the laser processing method and the laser processing device capable of shortening the processing time, improving the flatness of the cut surface, and reducing the influence of laser irradiation on the work piece.

### BRIEF DESCRIPTION OF THE DRAWINGS

FIG. 1 is a configuration view of a laser processing device according to an embodiment.

FIG. 2 is a plan view of a work piece in a laser processing method according to the embodiment.

FIG. 3 is a cross-sectional view of the work piece.

FIG. 4A is a view for describing one example of a modified spot forming step, and FIG. 4B is a view for describing another example of the modified spot forming step.

FIG. 5 is a view showing an example of a result of actually processing the work piece.

FIG. 6 is a plan view of a work piece in a laser processing method according to a first modification example.

FIG. 7A is a view for describing one example of a modified spot forming step according to the first modification example, and FIG. 7B is a view for describing another example of the modified spot forming step according to the first modification example.

FIG. 8 is a perspective view of a work piece in a laser processing method according to a second modification example.

FIG. 9 is a cross-sectional view of the work piece of FIG. 8.

FIG. 10 is a bottom view of the work piece of FIG. 8.

FIG. 11A is a view for describing a first example of a modified spot forming step according to a third modification example, and FIG. 11B is a view for describing a second example of the modified spot forming step according to the third modification example.

FIG. 12 is a view for describing a laser processing method according to a fourth modification example.

### DETAILED DESCRIPTION

Hereinafter, an embodiment of the present disclosure will be described in detail with reference to the drawings. In the following description, the same reference signs are used to denote the same or equivalent elements, and duplicate descriptions will be omitted.

### [Configuration of Laser Processing Device]

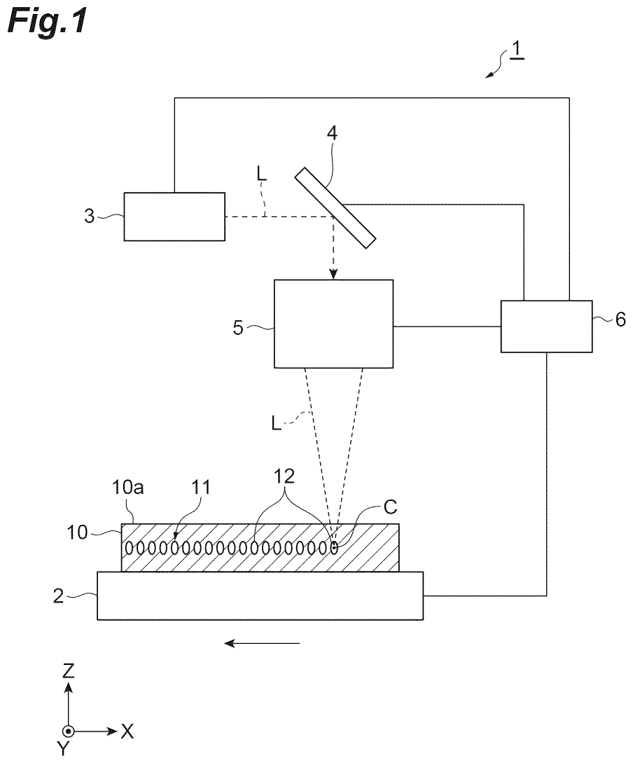

As shown in FIG. 1, a laser processing device 1 includes a stage 2, a light source 3, a spatial light modulator 4, a condenser lens 5, and a control unit 6. The laser processing device 1 is a device that forms a modified region 11 in a work piece 10 (processing object) by irradiating the work piece 10 with laser light L. Hereinafter, a first horizontal direction is referred to as an X direction, and a second horizontal direction perpendicular to the first horizontal direction is referred to as a Y direction. In addition, a vertical direction is referred to as a Z direction.

The stage 2 supports the work piece 10, for example, by suctioning a film affixed to the work piece 10. In this example, the stage 2 is movable along each of the X direction and the Y direction. In addition, the stage 2 is rotatable around an axis parallel to the Z direction as a central axis.

The light source 3 outputs the laser light L transmittable through the work piece 10, for example, through a pulse oscillation method. The spatial light modulator 4 modulates the laser light L output from the light source 3. The spatial light modulator 4 is, for example, a reflection-type liquid crystal on silicon (LCOS)-spatial light modulator (SLM). The condenser lens 5 condenses the laser light L modulated by the spatial light modulator 4. In this example, the spatial light modulator 4 and the condenser lens 5 are movable along the Z direction as a laser irradiation unit.

When the laser light L is condensed inside the work piece 10 supported by the stage 2, the laser light L is absorbed particularly at a portion corresponding to a condensing point C of the laser light L, and the modified region 11 is formed inside the work piece 10. The modified region 11 is a region different from a surrounding non-modified region in density, refractive index, mechanical strength, and other physical characteristics. Examples of the modified region 11 include a melting region, a crack region, a dielectric breakdown region, and a refractive index change region.

As one example, when the stage 2 is moved along the X direction to move the condensing point C relative to the work piece 10 along the X direction, a plurality of modified spots 12 are formed to be arranged in one row along the X direction. One modified spot 12 is formed by irradiation with one pulse of the laser light L. One row of the modified regions 11 are a collection of the plurality of modified spots 12 arranged in one row. The modified spots 12 adjacent to each other may be connected to each other or may be separated from each other depending on the relative movement speed of the condensing point C with respect to the work piece 10 and on the repetition frequency of the laser light L.

The control unit 6 controls the stage 2, the light source 3, the spatial light modulator 4, and the condenser lens 5. The control unit 6 is configured as a computer device including a processor, a memory, a storage, a communication device, and the like. In the control unit 6, software (program) read into the memory or the like is executed by the processor, the reading and writing of data in the memory and the storage and communication by the communication device are controlled by the processor. Accordingly, the control unit 6 realizes various functions.

### [Laser Processing Method and Semiconductor Device Manufacturing Method]

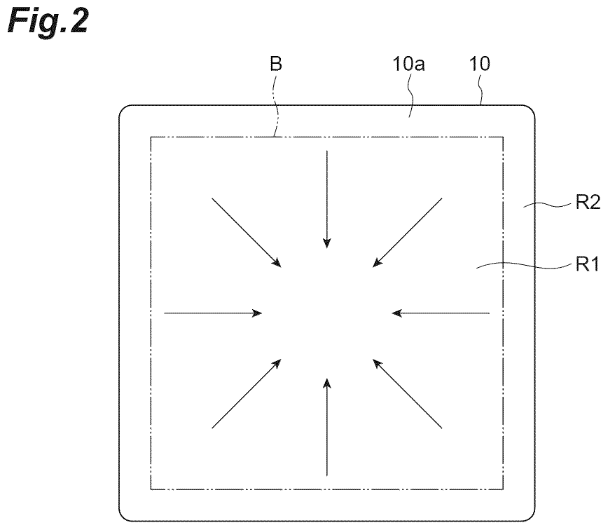

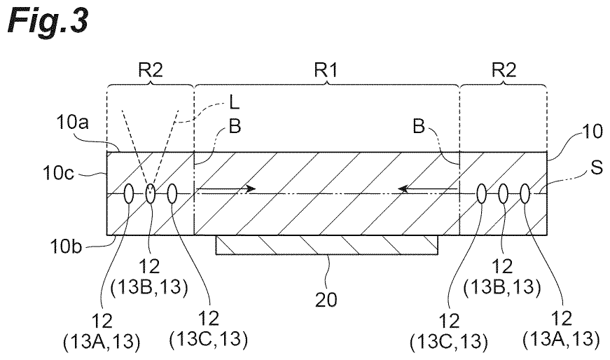

FIG. 2 is a plan view of the work piece 10 in a laser processing method and a semiconductor device manufacturing method according to the embodiment, and FIG. 3 is a cross-sectional view of the work piece 10. In the laser processing method, the work piece 10 is cut (sliced and peeled) along an imaginary plane S facing a surface 10a of the work piece 10 inside the work piece 10. In this example, the work piece 10 is a semiconductor object made of a semiconductor material. The work piece 10 has a chip shape, and forms one semiconductor device (semiconductor chip) after processing. In this example, the work piece 10 is formed in a rectangular plate shape. Examples of the semiconductor material forming the work piece 10 include gallium nitride (GaN), silicon carbide (SiC), sapphire, silicon (Si), and gallium arsenide (GaAs).

The laser processing method according to the embodiment includes a modified spot forming step of forming a plurality of the modified spots 12 along the imaginary plane S by irradiating the inside of the work piece 10 with the laser light L from the surface 10a of the work piece 10. The modified spot forming step is executed by the laser processing device 1. In this example, the imaginary plane S is a rectangular plane facing the surface 10a inside the work piece 10, and extends parallel to the surface 10a to reach a side surface 10c of the work piece 10. The work piece 10 has the surface 10a and a surface 10b opposite to the surface 10a. The surface 10a is a surface on which the laser light L output from the laser processing device 1 is incident.

The work piece 10 has a first region R1 and a second region R2 in a plan view (when viewed in a direction perpendicular to the surfaces 10a and 10b (thickness direction of the work piece 10)). In this example, the first region R1 has a rectangular shape, and the second region R2 has a rectangular ring shape surrounding the first region R1. The second region R2 extends along an outer edge of the work piece 10, and forms a peripheral edge portion of the work piece 10.

The first region R1 is an effective region used for forming a device portion 20. On the other hand, the second region R2 is a non-effective region in which the device portion 20 is not formed. The device portion 20 is, for example, formed on the surface 10b of the work piece 10 in the first region R1. The device portion 20 is, for example, an element portion for performing any function, for example, a light-emitting element, a light-receiving element, a circuit element, or the like. A plurality of the device portions 20 may be formed in the first region R1. The device portion 20 may be formed before the modified spot forming step, or may be formed after the modified spot forming step. Namely, a device forming step of forming the device portion 20 in the first region R1 may be executed before the modified spot forming step, or may be executed after the modified spot forming step. Hereinafter, the former case will be described as an example. In this case, in the modified spot forming step, in a state where the device portion 20 is formed in the first region R1, the modified spots 12 are formed in the work piece 10.

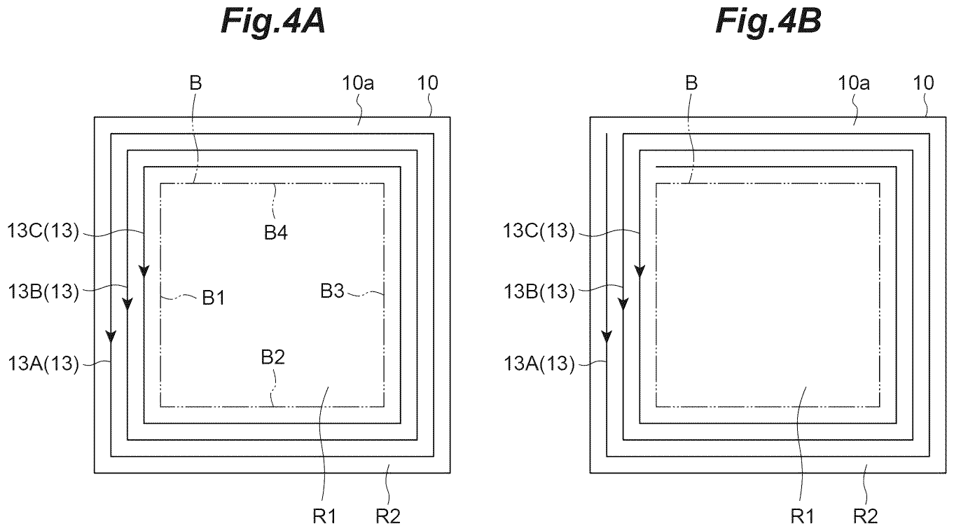

As shown in FIG. 4A, in the modified spot forming step, a plurality (three rows in this example) of modified spot rows 13 are formed in the second region R2. Each of the modified spot rows 13 is formed of a plurality of the modified spots 12 arranged along a boundary B between the first region R1 and the second region R2. In FIG. 4A, the disposition and formation order of the plurality of modified spots 12 forming each of the modified spot rows 13 are indicated by arrows. This point is also the same for FIGS. 4B, 7A, 7B, 11A, and 11B to be described later. The plurality of modified spot rows 13 are arranged along a direction intersecting an arrangement direction of the plurality of modified spots 12 (in this example, a direction perpendicular to the arrangement direction). Namely, in this example, the boundary B has a rectangular shape, and has a first side B1, a second side B2, a third side B3, and a fourth side B4. The first side B1 and the third side B3 are parallel to each other, and the second side B2 and the fourth side B4 are parallel to each other. Each of the modified spot rows 13 is formed of a plurality of the modified spots 12 arranged along each of the first side B1 to the fourth side B4. The plurality of modified spots 12 forming each of the modified spot rows 13 are arranged in a rectangular shape in a plan view. In a portion along the first side B 1, the plurality of modified spot rows 13 are arranged along the direction perpendicular to the arrangement direction (direction parallel to the first side B1) of the plurality of modified spots 12 (direction perpendicular to the first side B1). The same applies to portions along the second side B2 to the fourth side B4.

In the example of FIG. 4A, the plurality of modified spot rows 13 include a first modified spot row 13A, a second modified spot row 13B, and a third modified spot row 13C. The third modified spot row 13C, the second modified spot row 13B, and the first modified spot row 13A are disposed in order of proximity to the first region R1 (boundary B). In the modified spot forming step, the plurality of modified spot rows 13 are formed in order of increasing distance from the first region R1. In this example, the plurality of modified spot rows 13 are formed in order of the first modified spot row 13A, the second modified spot row 13B, and the third modified spot row 13C.

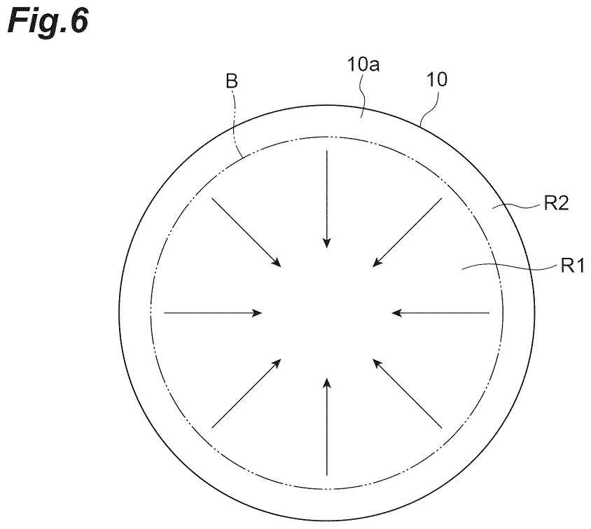

In the modified spot forming step, cracks extending from the second region R2 to the first region R1 are formed by forming the plurality of modified spot rows 13 in the second region R2. More specifically, cracks extending from the modified spots 12 formed in the second region R2 extend toward a first region R1 side (toward a center side of the work piece 10), so that the cracks extending from the second region R2 to the first region R1 are formed. In FIGS. 2 and 3, directions in which the cracks extend are indicated by arrows. This point is also the same for FIG. 6. In this example, cracks are formed over the entirety of the first region R1 by forming the plurality of modified spot rows 13 in the second region R2.

In the modified spot forming step, the plurality of modified spot rows 13 may be formed in the second region R2 as shown in FIG. 4B. In this example, the plurality of modified spots 12 are disposed to be arranged and connected in a substantially vortex shape (spiral shape) in a plan view. In this case as well, it can be considered that the plurality of modified spot rows 13 arranged along the direction perpendicular to the arrangement direction of the plurality of modified spots 12 are formed. Namely, similarly to the example of FIG. 4A, it can be considered that the plurality of modified spot rows 13 include the first modified spot row 13A, the second modified spot row 13B, and the third modified spot row 13C.

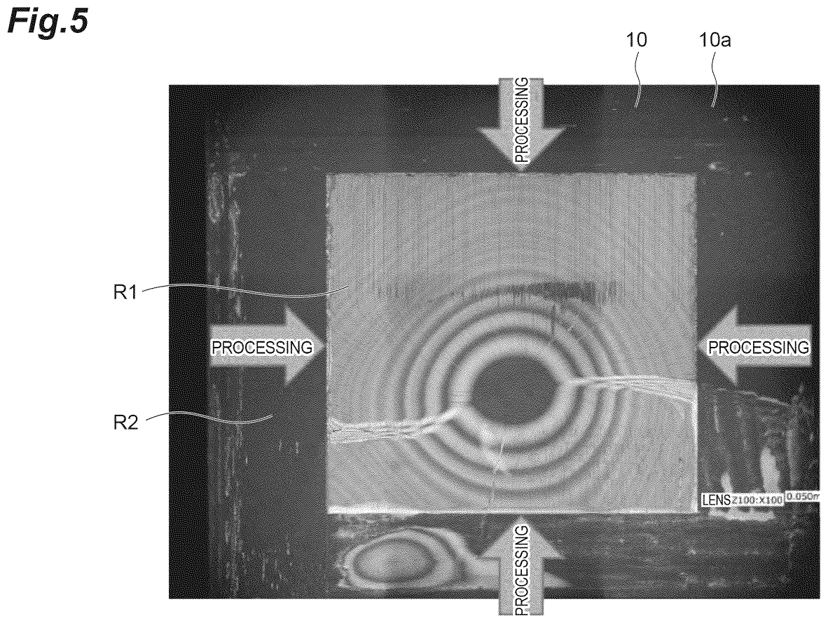

FIG. 5 is a view showing an example of a result of actually processing the work piece 10. FIG. 5 shows the work piece 10 when viewed from a surface 10a side. In this example, a member formed in a rectangular plate shape from magnesium oxide (MgO) was used as the work piece 10. A surface orientation of the surface 10a of the work piece 10 was <100>, a length of a side of the surface 10a was 5 mm, and a thickness of the work piece 10 was 500 μm. A region with a width of 1 mm was set as the second region R2. Therefore, the first region R1 was a square region with a side of 3 mm. Similarly to the example of FIG. 4A, three modified spot rows 13 were formed in the second region R2. Arrows in FIG. 5 indicate the order in which a plurality of the modified spot rows 13 are formed. In this example, similarly to FIG. 4A, the plurality of modified spot rows 13 were formed in order of increasing distance from the first region R1. In the work piece 10 after processing, cracks extending from the second region R2 to the first region R1 were formed. The cracks were formed over the entirety of the first region R1. Since cracks extending from the modified spots 12 formed in four side portions of the second region R2 were connected in a central portion of the first region R1, a closed region (closed space) in which the cracks were connected was formed within the second region R2.

The laser processing method according to the embodiment further includes a separation step of separating the work piece 10 with the imaginary plane S as the boundary after the modified spot forming step. In the separation step, for example, by affixing double-sided tape to the surfaces 10a and 10b of the work piece 10 and by applying a force to the work piece 10 to separate the surfaces 10a and 10b from each other, the work piece 10 is separated into two portions with the imaginary plane S as the boundary. Of the separated two portions, a portion which includes the surface 10b and on which the device portion 20 is formed forms a semiconductor device. Through the above steps, the semiconductor device in which the device portion 20 is formed in the first region R1 is obtained. Incidentally, the separation step is not limited to the above-described mode, and the work piece 10 may be separated, for example, by applying some force to the work piece 10 without affixing double-side tape to the surfaces 10a and 10b.

### Functions and Effects

In the laser processing method according to the embodiment, cracks extending from the second region R2 to the first region R1 are formed by forming a plurality of the modified spot rows 13 in the second region R2. Since cracks are formed by extending (propagating) from the second region R2 to the first region R1 in such a manner (namely, since cracks extend using the cleavage property of the work piece 10), for example, compared to when cracks are formed in the first region R1 by forming the modified spots 12 in the first region R1, the processing time can be shortened, and the flatness of a cut surface can be improved. Namely, when cracks are formed in the first region R1 by forming the modified spots 12 in the first region R1, unevenness can occur on the cut surface due to laser processing traces (modified spots 12) remaining on the cut surface, whereas in the laser processing method according to the embodiment, since cracks are formed by extending from the second region R2 to the first region R1, the occurrence of such unevenness can be suppressed, and the flatness of the cut surface can be improved. In addition, in the laser processing method according to the embodiment, cracks extending from the second region R2 to the first region R1 are formed by forming the plurality of modified spot rows 13 in the second region R2. Accordingly, the influence of laser irradiation on the first region R1 can be reduced, and as a result, the influence of laser irradiation on the device portion 20 formed in the first region R1 can be reduced. For example, when the modified spots 12 are formed by irradiating the first region R1 with the laser light L in a state where the device portion 20 is formed in the first region R1, there is a possibility that the laser light L which has transmitted through the work piece 10 is incident on the device portion 20 to adversely affect the device portion 20. Alternatively, even when the modified spots 12 are formed by irradiating the first region R1 with the laser light L before the device portion 20 is formed in the first region R1, and the device portion 20 is formed in the first region R1 after the modified spots 12 are formed, since the device portion 20 is formed in the first region R1 damaged by the laser irradiation, there is a possibility that the device portion 20 is adversely affected. In contrast, in the laser processing method according to the embodiment, since cracks extending from the second region R2 to the first region R1 are formed by forming the plurality of modified spot rows 13 in the second region R2, the occurrence of such a situation can be suppressed, and the influence of laser irradiation on the device portion 20 formed in the first region R1 can be reduced. Therefore, in the laser processing method according to the embodiment, the processing time can be shortened, the flatness of the cut surface can be improved, and the influence of laser irradiation on the work piece 10 can be reduced. Incidentally, the finding that cracks extending from the second region R2 to the first region R1 can be formed by forming the modified spot rows 13 formed of the plurality of modified spots 12, which are arranged along the boundary B between the first region R1 and the second region R2, in the second region R2 so as to be arranged along the direction intersecting the arrangement direction of the plurality of modified spots 12 is a finding discovered by the inventors.

In the modified spot forming step, the plurality of modified spot rows 13 are formed in the second region R2 such that cracks are formed over the entirety of the first region R1. Accordingly, the processing time can be further shortened, and the flatness of the cut surface can be further improved.

In the modified spot forming step, after the first modified spot row 13A is formed, the second modified spot row 13B disposed closer to the first region R1 than the first modified spot row 13A is formed. Accordingly, cracks easily extend from the second region R2 to the first region R1, so that the processing time can be further shortened and the flatness of the cut surface can be further improved. Incidentally, the finding that when the plurality of modified spot rows 13 are formed in order of increasing distance from the first region R1, cracks easily extend from the second region R2 to the first region R1 is a finding discovered by the inventors.

The second region R2 surrounds the first region R1 in a plan view. Accordingly, cracks can suitably extend from the second region R2 to the first region R1, so that the processing time can be further shortened and the flatness of the cut surface can be further improved.

Examples of the material of the work piece 10 include gallium nitride, silicon carbide, sapphire, silicon, and gallium arsenide. In the laser processing method according to the embodiment, even in such a case, the processing time can be shortened, the flatness of the cut surface can be improved, and the influence of laser irradiation on the work piece 10 can be reduced.

The work piece 10 has a chip shape. In the laser processing method according to the embodiment, even in such a case, the processing time can be shortened, the flatness of the cut surface can be improved, and the influence of laser irradiation on the work piece 10 can be reduced.

The work piece 10 is made of a semiconductor material. In the laser processing method according to the embodiment, a semiconductor object made of a semiconductor material can be suitably cut as the work piece 10.

The first region R1 is a region for forming the device portion 20, and the second region R2 is a region in which the device portion 20 is not formed. In the laser processing method according to the embodiment, the influence of laser irradiation on the device portion 20 can be reduced.

In the modified spot forming step, in a state where the device portion 20 is formed in the first region R1, the plurality of modified spot rows 13 are formed in the second region R2. In this case, the influence of laser irradiation on the device portion 20 formed in the first region R1 can be reduced.

After the modified spot forming step, the separation step of separating the work piece 10 with the imaginary plane S as the boundary is executed. Accordingly, the work piece 10 can be suitably separated.

### MODIFICATION EXAMPLES

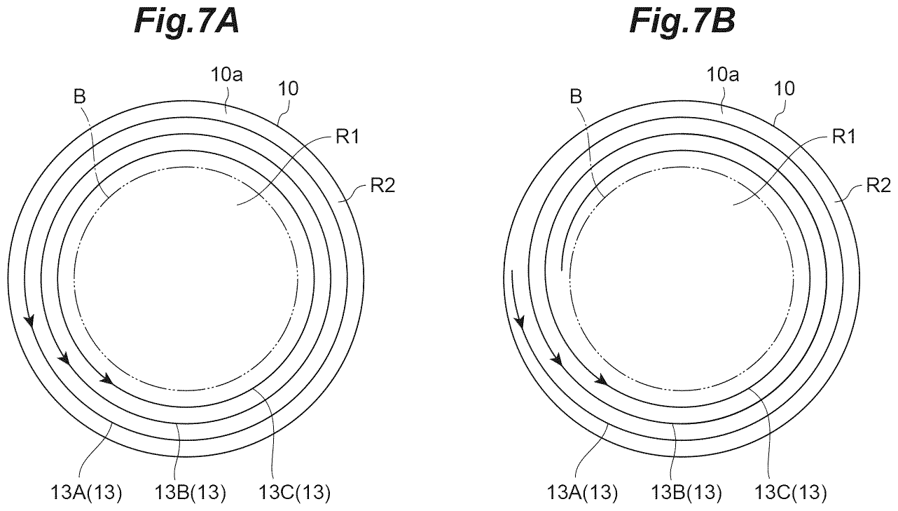

As in a first modification example shown in FIGS. 6, 7A, and 7B, the work piece 10 may be formed in a circular shape in a plan view. In this case, the imaginary plane S is a circular surface facing the surface 10a inside the work piece 10. In this example, the first region R1 has a circular shape, and the second region R2 has a circular ring shape (annular shape) surrounding the first region R1. The boundary B between the first region R1 and the second region R2 has a circular shape.

As shown in FIG. 7A, in the modified spot forming step, a plurality (three rows in this example) of the modified spot rows 13 are formed in the second region R2. The plurality of modified spot rows 13 are arranged along a direction intersecting an arrangement direction of a plurality of the modified spots 12 (in this example, a radial direction), and are concentrically disposed. The plurality of modified spot rows 13 include the first modified spot row 13A, the second modified spot row 13B, and the third modified spot row 13C. The third modified spot row 13C, the second modified spot row 13B, and the first modified spot row 13A are disposed in order of proximity to the first region R1 (boundary B). In the modified spot forming step, the plurality of modified spot rows 13 are formed in order of increasing distance from the first region R1. In this example, the plurality of modified spot rows 13 are formed in order of the first modified spot row 13A, the second modified spot row 13B, and the third modified spot row 13C. In the modified spot forming step of the first modification example as well, cracks extending from the second region R2 to the first region R1 are formed over the entirety of the first region R1 by forming the plurality of modified spot rows 13 in the second region R2.

In the modified spot forming step of the first modification example, the plurality of modified spot rows 13 may be formed in the second region R2 as shown in FIG. 7B. In this example, the plurality of modified spots 12 are disposed to be arranged and connected in a vortex shape in a plan view. In this case as well, it can be considered that the plurality of modified spot rows 13 arranged along a direction perpendicular to the arrangement direction of the plurality of modified spots 12 are formed. Namely, similarly to the example of FIG. 7A, it can be considered that the plurality of modified spot rows 13 include the first modified spot row 13A, the second modified spot row 13B, and the third modified spot row 13C.

In the first modification example as well, similarly to the embodiment, the processing time can be shortened, the flatness of a cut surface can be improved, and the influence of laser irradiation on the work piece 10 can be reduced.

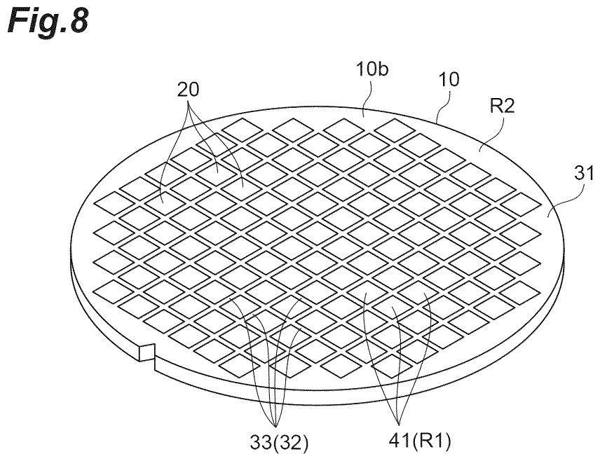

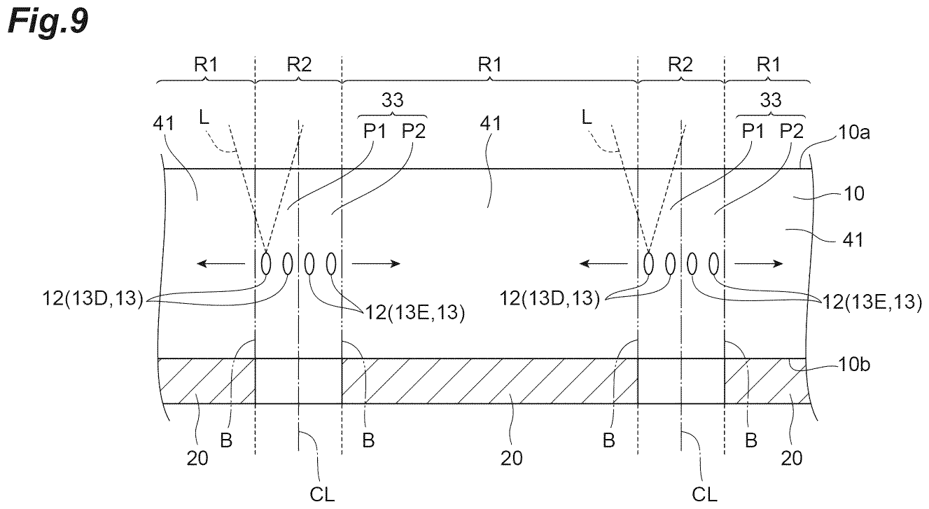

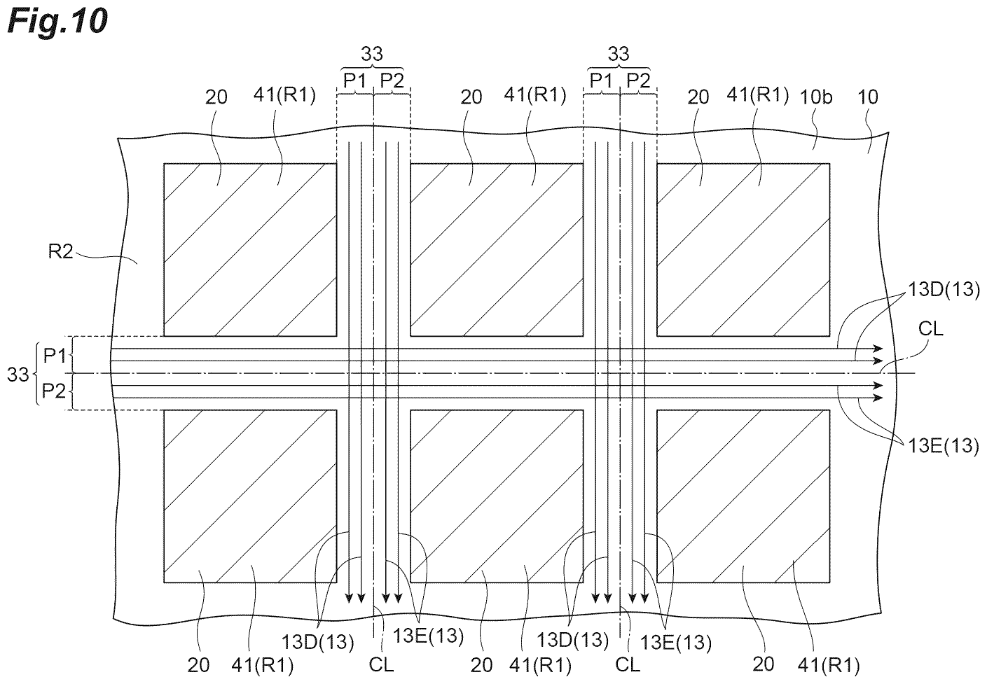

As in a second modification example shown in FIGS. 8, 9, and 10, the work piece 10 may have a wafer shape. The work piece 10 of the second modification example is, for example, a semiconductor wafer formed in a disk shape from a semiconductor material. A plurality of semiconductor devices (semiconductor chips) are obtained by cutting and dicing the work piece 10 along linear portions 33 to be described later.

The second region R2 of the second modification example includes a peripheral edge portion 31 having a circular ring shape and forming a peripheral edge portion of the work piece 10, and a grid-shaped portion 32 having a grid shape. The grid-shaped portion 32 includes a plurality of the linear portions 33. Some of the plurality of linear portions 33 are arranged along one direction, and the rest of the plurality of linear portions 33 are arranged along a direction perpendicular to the one direction. The grid-shaped portion 32 is a cutting region (dicing street) for cutting the work piece 10. The first region R1 includes a plurality of rectangular portions 41 surrounded by the plurality of linear portions 33. The device portion 20 is formed in each of the rectangular portions 41.

Regarding each of the linear portions 33 (reference linear portion), a region on one side with respect to a center line CL of the linear portion 33 in a plan view is defined as a first portion P1, and a region on the other side with respect to the center line CL is defined as a second portion P2. The center line CL is a straight line passing through a center in a width direction of the linear portion 33 and extending along an extending direction of the linear portion 33 in a plan view.

In the modified spot forming step, a plurality of the modified spot rows 13 are formed in the peripheral edge portion 31. A mode of forming the plurality of modified spot rows 13 in the peripheral edge portion 31 is, for example, the same as the mode of forming the plurality of modified spot rows 13 in the second region R2 in the first modification example. In addition, a plurality (two in this example) of first modified spot rows 13D are formed in the first portion P1, and a plurality (two in this example) of second modified spot rows 13E are formed in the second portion P2. More specifically, the plurality of first modified spot rows 13D are formed in order of proximity to the center line CL (namely, in order of increasing distance from the first region R1), and the plurality of second modified spot rows 13E are formed in order of proximity to the center line CL. In the modified spot forming step of the second modification example as well, cracks extending from the second region R2 to the first region R1 are formed over the entirety of the first region R1 (rectangular portions 41) by forming the plurality of modified spot rows 13 in the second region R2.

In the second modification example as well, similarly to the embodiment, the processing time can be shortened, the flatness of a cut surface can be improved, and the influence of laser irradiation on the work piece 10 can be reduced.

In addition, in the second modification example, the second region R2 includes the grid-shaped portion 32 including the plurality of linear portions 33, and the first region R1 includes the plurality of rectangular portions 41 surrounded by the plurality of linear portions 33. In this case, cracks easily extend from the second region R2 to the first region R1, so that the processing time can be further shortened and the flatness of the cut surface can be further improved. In addition, for example, a cutting region having a grid shape for dicing a semiconductor wafer can be used as the second region R2.

In the modified spot forming step of the second modification example, the first modified spot rows 13D are formed in the first portion P1, and the second modified spot rows 13E are formed in the second portion P2. Accordingly, cracks easily extend from the second region R2 to the first region R1, so that the processing time can be further shortened and the flatness of the cut surface can be further improved.

In the modified spot forming step of the second modification example, the plurality of first modified spot rows 13D are formed in the first portion P1 in order of proximity to the center line CL, and the plurality of second modified spot rows 13E are formed in the second portion P2 in order of proximity to the center line CL. Accordingly, cracks easily extend from the second region R2 to the first region R1, so that the processing time can be further shortened and the flatness of the cut surface can be further improved.

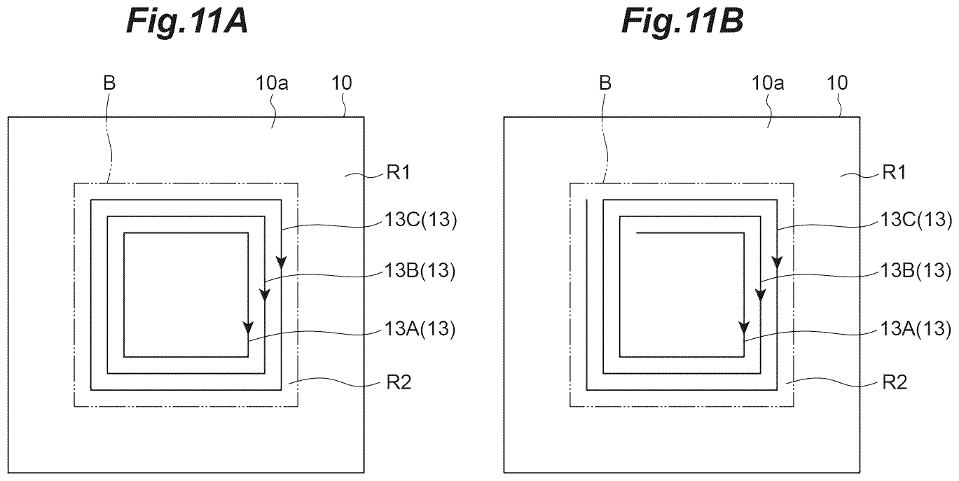

As in a third modification example shown in FIGS. 11A and 11B, the first region R1 and the second region R2 may be set. In the third modification example, the second region R2 has a rectangular shape, and the first region R1 has a rectangular ring shape surrounding the second region R2. The first region R1 extends along the outer edge of the work piece 10, and forms the peripheral edge portion of the work piece 10. In the first region R1, the device portion 20 may be formed or the device portion 20 may not be formed.

As shown in FIG. 11A, in the modified spot forming step, a plurality (three rows in this example) of the modified spot rows 13 are formed in the second region R2. The plurality of modified spot rows 13 include the first modified spot row 13A, the second modified spot row 13B, and the third modified spot row 13C. The third modified spot row 13C, the second modified spot row 13B, and the first modified spot row 13A are disposed in order of proximity to the first region R1 (boundary B). In the modified spot forming step, the plurality of modified spot rows 13 are formed in order of increasing distance from the first region R1. In this example, the plurality of modified spot rows 13 are formed in order of the first modified spot row 13A, the second modified spot row 13B, and the third modified spot row 13C. In the modified spot forming step of the third modification example as well, cracks extending from the second region R2 to the first region R1 are formed over the entirety of the first region R1 by forming the plurality of modified spot rows 13 in the second region R2. In the third modification example, cracks extending from the modified spots 12 formed in the second region R2 extend toward the first region R1 side (toward an outer edge side of the work piece 10), so that the cracks extending from the second region R2 to the first region R1 are formed.

In the modified spot forming step of the third modification example, the plurality of modified spot rows 13 may be formed in the second region R2 as shown in FIG. 11B. In this example, a plurality of the modified spots 12 are disposed to be arranged and connected in a substantially vortex shape in a plan view. In this case as well, it can be considered that the plurality of modified spot rows 13 arranged along a direction perpendicular to an arrangement direction of the plurality of modified spots 12 are formed. Namely, similarly to the example of FIG. 11A, it can be considered that the plurality of modified spot rows 13 include the first modified spot row 13A, the second modified spot row 13B, and the third modified spot row 13C.

In the third modification example as well, similarly to the embodiment, the processing time can be shortened, the flatness of a cut surface can be improved, and the influence of laser irradiation on the work piece 10 can be reduced.

As a fourth modification example, in the modified spot forming step, a plurality of the modified spot rows 13 may be simultaneously formed by branching the laser light L and by performing an irradiation with the branched laser light L. In this case, for example, the laser light L oscillated in a pulsed manner by the light source 3 is modulated by the spatial light modulator 4 to be condensed at a plurality (for example, six) of the condensing points C arranged in the Y direction. Then, the plurality of condensing points C are moved on the imaginary plane S along the X direction relative to the imaginary plane S. Accordingly, the plurality of modified spot rows 13 formed of a plurality of the modified spots 12 arranged along the X direction are simultaneously formed to be arranged at equal intervals in the Y direction.

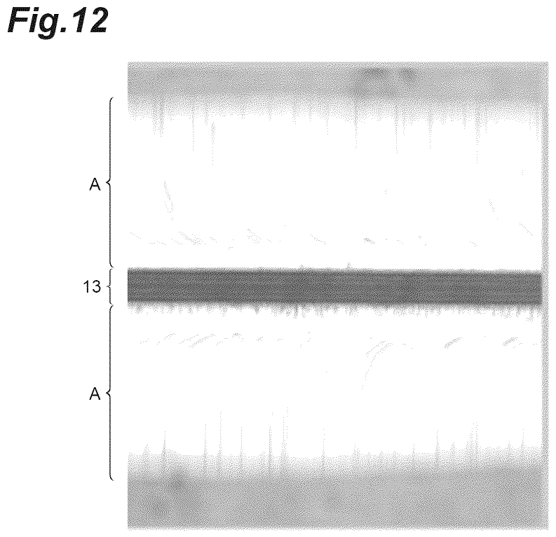

FIG. 12 is a view showing a result of simultaneously forming six modified spot rows 13 by branching the laser light L at six points and by performing an irradiation with the branched laser light L. In this example, a member made of magnesium oxide (MgO) was used as a work piece. FIG. 12 shows the work piece when viewed from a surface. In FIG. 12, the six modified spot rows 13 are formed to be arranged in an up-down direction in the drawing. In the work piece after processing, cracks extending from a region in which the six modified spot rows 13 were formed (second region R2) to each of a pair of regions A (first region R1) adjacent to the region were formed. In addition, cracks were not formed on the surface of the work piece, and cracks were formed only inside the work piece.

In the fourth modification example as well, similarly to the embodiment, the processing time can be shortened, the flatness of a cut surface can be improved, and the influence of laser irradiation on the work piece 10 can be reduced. In addition, in the modified spot forming step of the fourth modification example, the plurality of modified spot rows 13 may be simultaneously formed by branching the laser light L and by performing an irradiation with the branched laser light L. In this case, cracks easily extend from the second region R2 to the first region R1, so that the processing time can be further shortened and the flatness of the cut surface can be further improved. Incidentally, the finding that when the plurality of modified spot rows 13 are simultaneously formed by branching the laser light L and by performing an irradiation with the branched laser light L, cracks easily extend from the second region R2 to the first region R1 is a finding discovered by the inventors. In the fourth modification example, at least two modified spot rows 13 may be simultaneously formed by branching the laser light L and by performing an irradiation with the branched laser light L, for example, two modified spot rows 13 may be simultaneously formed by branching the laser light L at two points and by performing an irradiation with the branched laser light L.

The present disclosure is not limited to the embodiment and the modification examples. For example, the material and the shape of each configuration are not limited to the material and the shape described above, and various materials and shapes can be adopted. The material of the work piece 10 may be a non-semiconductor material such as magnesium oxide (MgO), magnesium fluoride (MgF), calcium fluoride (CaF₂), or mica. The work piece 10 may have an ingot shape. For example, the work piece 10 may be a semiconductor ingot formed in a disk shape from a semiconductor material. A semiconductor wafer can be cut off from the semiconductor ingot by cutting the semiconductor ingot along the imaginary plane S facing a surface of the semiconductor ingot.

In the embodiment and the modification examples, one imaginary plane S is set inside the work piece 10, and the work piece 10 is separated into two portions; however, two or more imaginary planes S arranged in the thickness direction may be set inside the work piece 10, and the work piece 10 may be separated into three or more portions. In the embodiment and the modification examples, the modified spot forming step is executed after the device forming step; however, the device forming step may be executed after the modified spot forming step. In this case, in the modified spot forming step, in a state where the device portion 20 is not formed in the first region R1, a plurality of the modified spot rows 13 are formed in the work piece 10.

In the modified spot forming step of the embodiment and the modification examples, cracks are formed over the entirety of the first region R1 by forming the plurality of modified spot rows 13 in the second region R2; however, cracks may be partially formed in the first region R1 by forming the plurality of modified spot rows 13 in the second region R2. Even in this case, the work piece 10 can be separated into two portions with the imaginary plane S as the boundary, for example, by applying a force to the work piece 10 in the separation step.

In the embodiment and the modification examples, the modified spot rows 13 are not formed in a portion of the work piece 10 in which the device portion 20 is formed in a plan view; however, the modified spot rows 13 may be formed in a part of the portion. Namely, the device portion 20 may be formed in the second region R2. In the embodiment and the modification examples, the device portion 20 is formed on the surface 10b of the work piece 10 in the first region R1; however, instead or additionally, the device portion 20 may be formed on the surface 10a of the work piece 10 in the first region R1.

What is claimed is:

1. A laser processing method for cutting a work piece along an imaginary plane facing a surface of the work piece inside the work piece, the method comprising:
a forming step of forming a plurality of modified spots along the imaginary plane by irradiating an inside of the work piece with laser light from the surface,
wherein the work piece includes a first region and second region when viewed in a direction perpendicular to the surface, and
in the forming step, a plurality of modified spot rows formed of the plurality of modified spots arranged along a boundary between the first region and the second region are formed in the second region, the plurality of modified spot rows being arranged along a direction intersecting an arrangement direction of the plurality of modified spots, and a crack extending from the second region to the first region is formed by forming the plurality of modified spot rows.

2. The laser processing method according to claim 1,
wherein in the forming step, the plurality of modified spot rows are formed in the second region such that the crack is formed over an entirety of the first region.

3. The laser processing method according to claim 1,
wherein the plurality of modified spot rows include a first modified spot row, and a second modified spot row disposed closer to the first region than the first modified spot row, and
in the forming step, after the first modified spot row is formed, the second modified spot row is formed.

4. The laser processing method according to claim 1,
wherein the second region includes a portion surrounding the first region when viewed in the direction perpendicular to the surface.

5. The laser processing method according to claim 1,
wherein in the forming step, at least two modified spot rows included in the plurality of modified spot rows are simultaneously formed by branching the laser light and by performing an irradiation with the branched laser light.

6. The laser processing method according to claim 1,
wherein the second region includes a grid-shaped portion including a plurality of linear portions, and
the first region includes a plurality of rectangular portions surrounded by the plurality of linear portions.

7. The laser processing method according to claim 6,
wherein when one linear portion included in the plurality of linear portions is defined as a reference linear portion, and a region on one side of the reference linear portion with respect to a center line of the reference linear portion extending along an extending direction of the reference linear portion when viewed in the direction perpendicular to the surface is defined as a first portion, and a region on the other side of the reference linear portion with respect to the center line is defined as a second portion, in the forming step, at least one modified spot row included in the plurality of modified spot rows is formed in the first portion, and at least one modified spot row included in the plurality of modified spot rows is formed in the second portion.

8. The laser processing method according to claim 7,
wherein the at least one modified spot row formed in the first portion includes a plurality of first modified spot rows, and the at least one modified spot row formed in the second portion includes a plurality of second modified spot rows, and
in the forming step, the plurality of first modified spot rows are formed in the first portion in order of proximity to the center line, and the plurality of second modified spot rows are formed in the second portion in order of proximity to the center line.

9. The laser processing method according to claim 1,
wherein a material of the work piece includes gallium nitride, silicon carbide, sapphire, silicon, gallium arsenide, magnesium oxide, magnesium fluoride, calcium fluoride, or mica.

10. The laser processing method according to claim 1,
wherein the work piece has a chip shape, a wafer shape, or an ingot shape.

11. The laser processing method according to claim 1,
wherein the work piece is made of a semiconductor material.

12. The laser processing method according to claim 1,
wherein the first region is a region for forming a device portion, and the second region is a region in which the device portion is not formed.

13. The laser processing method according to claim 12,
wherein in the forming step, in a state where the device portion is formed in the first region, the plurality of modified spot rows are formed in the second region.

14. The laser processing method according to claim 12,
wherein in the forming step, in a state where the device portion is not formed in the first region, the plurality of modified spot rows are formed in the second region.

15. The laser processing method according to claim 1, further comprising:
a step of separating the work piece with the imaginary plane as a boundary after the forming step.

16. A semiconductor device manufacturing method using the laser processing method according to claim 1, the work piece being made of a semiconductor material, the method comprising:
the forming step; and
a step of forming a device portion in the first region.

17. A laser processing device that cuts a work piece along an imaginary plane facing a surface of the work piece inside the work piece, the device comprising:
a stage that supports the work piece; and
a laser irradiation unit that forms a plurality of modified spots along the imaginary plane by irradiating an inside of the work piece with laser light from the surface,
wherein the work piece includes a first region and second region when viewed in a direction perpendicular to the surface, and
the laser irradiation unit forms a plurality of modified spot rows in the second region, the plurality of modified spot rows being formed of the plurality of modified spots arranged along a boundary between the first region and the second region, the plurality of modified spot rows are arranged along a direction intersecting an arrangement direction of the plurality of modified spots, and a crack extending from the second region to the first region is formed by forming the plurality of modified spot rows.
